(19) United States
(12) Patent Application Publication
(10) Pub. No.: US 2008/0085472 A1
(43) Pub. Date: Apr. 10, 2008

(54) Method of fabricating semiconductor device

(76) Inventor: Hyoung-Joo Youn, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/653,363

(22) Filed: Jan. 16, 2007

(30) Foreign Application Priority Data
Oct. 9, 2006 (KR) 2006-98060

(51) Int. Cl. G03F 7/26

(52) U.S. Cl. 430/313; 430/311

(57) ABSTRACT

A method of fabricating a semiconductor device includes forming a first mask layer on a semiconductor substrate, forming a second mask layer on the first mask layer, patterning the first mask layer and the second mask layer to form a first mask pattern and a second mask pattern, respectively, the first and second mask layers having a plurality of first openings, widening an upper portion of the plurality of first openings to form a second fine mask pattern with a plurality of second openings having a larger width as compared to a width of the plurality of the first openings, forming a third mask pattern in the plurality of first and second openings, removing the second fine mask pattern, and etching the first mask pattern to form a first fine mask pattern.

### BACKGROUND OF THE INVENTION

1. Field of the Invention

The present invention disclosed herein relates to a method of fabricating a semiconductor device. More particularly, there present invention relates to a method of fabricating a semiconductor device with reduced linewidths.

2. Description of the Related Art

In general, as the integration level of a semiconductor device increases, the linewidth required to realize the device may be decreased. Accordingly, the width of a photoresist pattern, used as a mask, may be reduced in order to decrease the linewidth of the semiconductor device. However, when the linewidth of the semiconductor device is small, the photoresist pattern may deform during formation thereof.

In addition, high-performance exposure equipment may be required to obtain an appropriately small linewidth of the semiconductor device. However, development of high-performance exposure equipment may be cost-consuming and may require a stable light source and exposure technology.

Accordingly, there is a need for a method of fabricating a semiconductor device capable of forming a mask pattern with a small linewidth while using conventional exposure equipment.

### SUMMARY OF THE INVENTION

The present invention is therefore directed to a method of fabricating a semiconductor device having a reduced linewidth, which substantially overcome one or more of the problems due to the limitations and disadvantages of the related art.

It is therefore a feature of an embodiment of the present invention to provide a method of fabricating a semiconductor device with fine patterns having reduced linewidth.

At least one of the above and other features of the present invention may be realized by providing a method of fabricating a semiconductor device, including forming a first mask layer on a semiconductor substrate, forming a second mask layer on the first mask layer, patterning the first mask layer and the second mask layer to form a first mask pattern and a second mask pattern, respectively, the first and second mask layers having a plurality of first openings, widening an upper portion of the plurality of first openings to form a second fine mask pattern with a plurality of second openings having a larger width as compared to a width of the plurality of the first openings, forming a third mask pattern in the plurality of first and second openings, removing the second fine mask pattern, and etching the first mask pattern to form a first fine mask pattern.

The second mask layer may be formed to have an etch selectivity with respect to the first mask layer. The second mask layer may be formed of a silicon oxide layer and the first mask layer is formed of a silicon nitride layer. Alternatively, the second mask layer may be also s formed of a silicon nitride layer and the first mask layer is formed of a silicon oxide layer.

Etching the first mask pattern to form the first fine mask pattern may include removing the third mask pattern to expose the first fine mask pattern. The first fine mask pattern may be formed to have parallel lines in one direction.

The second fine mask pattern may be formed to have a width equal to a width of each of the plurality of the first openings. Widening the upper portion of the plurality of first openings to form the second fine mask pattern may include performing a pull-back process. The second fine mask pattern may be formed to have an etch selectivity with respect to the third mask pattern.

Forming the third mask pattern may include forming a third mask layer on the second fine mask pattern and the first mask pattern and planarizing the third mask layer to expose an upper surface of the second fine mask pattern. The third mask pattern may be formed of a polysilicon layer and the second fine mask pattern may be formed of a silicon oxide layer or a silicon nitride layer.

The method may further include forming a plurality of trenches in the semiconductor substrate via the first fine mask pattern, and forming a device isolation layer in the trenches. Additionally, the method may include forming a line layer on the semiconductor substrate before forming of the first mask layer, and etching the line layer using the first fine mask pattern as an etch mask to form a line pattern.

The method may further include forming a mold oxide layer on the semiconductor substrate. Additionally, the plurality of first openings may have circular shapes. The first fine mask pattern may be formed as a plurality of cylinders.

The method may also include etching the mold oxide layer via the fine mask pattern to form a cylindrical mold oxide layer pattern. Additionally, the method may include forming an amorphous carbon layer on the mold oxide layer and forming an anti-reflective layer on the amorphous carbon layer. The method may further include etching the amorphous carbon layer, the anti-reflective layer and the mold oxide layer via the fine mask pattern to form a cylindrical mold oxide layer pattern. Also, the method may include forming a metal layer with an opening on the cylindrical mold oxide layer pattern, forming a sacrificial oxide layer to fill the opening of the metal layer, planarizing the sacrificial oxide layer to expose the cylindrical mold oxide layer pattern, and removing the sacrificial oxide layer and the cylindrical mold oxide layer pattern to form an electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A-8A illustrate perspective views of sequential steps in fabricating a semiconductor device according to an exemplary method of the present invention;

FIGS. 1B-8B illustrate cross-sectional views of the sequential steps illustrated in FIGS. 1A-8A;

FIGS. 9A-16A illustrate perspective views of sequential steps in fabricating a semiconductor device according to another exemplary method of the present invention;

FIGS. 9B-16B illustrate cross-sectional views of the sequential steps illustrated in FIGS. 9A-16A;

FIGS. 17A-24A illustrate perspective views of sequential steps in fabricating a semiconductor device according to another exemplary method of the present invention;

FIGS. 17B-24B illustrate plan views of the sequential steps illustrated in FIGS. 17A-24A; and

FIGS. 17C-24C illustrate cross-sectional views of the sequential steps illustrated in FIGS. 17A-24A.

### DETAILED DESCRIPTION OF THE INVENTION

Korean Patent Application No. 2006-98060, filed on Oct. 9, 2006, in the Korean Intellectual Property Office, and entitled: “Method of Fabricating Semiconductor Device,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, or one or more intervening layers may also be present. In addition, it will also be understood that when a layer is referred to as being “between” two layers, it can be the only layer between the two layers, or one or more intervening layers may also be present. Like reference numerals refer to like elements throughout.

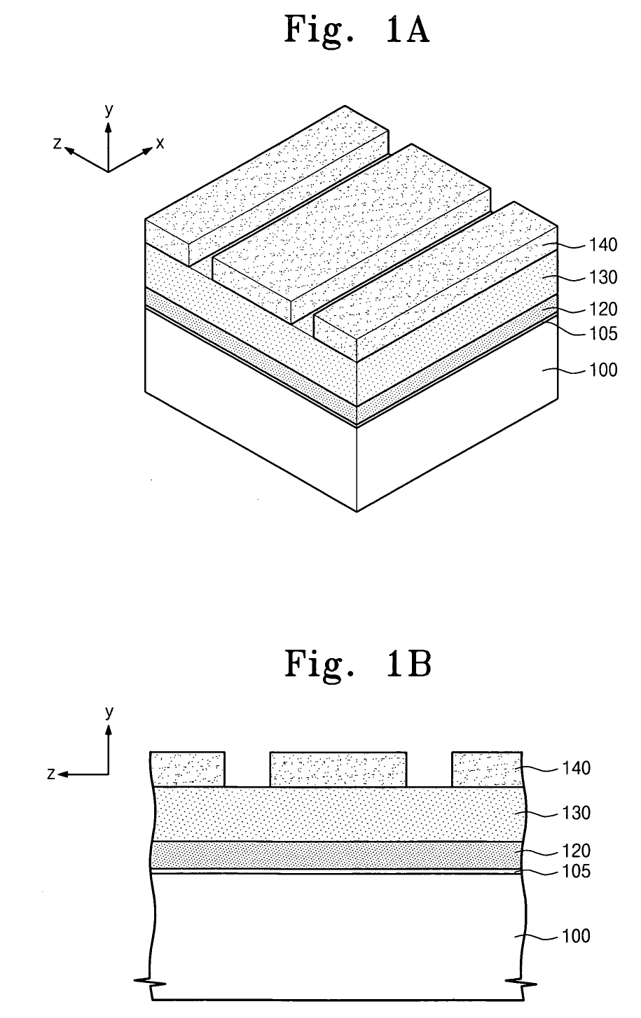

An exemplary embodiment of a method of fabricating a semiconductor device of the present invention will now be more fully described in conjunction with FIGS. 1A-8B. It should be noted that the axes-system as indicated in FIGS. 1A-1B is consistent throughout all the drawings and the specification.

As illustrated in FIGS. 1A-1B, a pad oxide layer 105 may be formed on a semiconductor substrate 100. The pad oxide layer 105 may be formed by thermal oxidation or by chemical vapor deposition (CVD). A first mask layer 120 having a thermal expansion coefficient different than the substrate 100 may be formed of a silicon nitride layer on the pad oxide layer 105 by CVD. Therefore, the pad oxide layer 105 may be positioned between the first mask layer 120 and the substrate 100 to reduce stress due to the difference between the thermal expansion coefficients thereof.

A second mask layer 130 made of silicon oxide layer may be formed on the first mask layer 120 by CVD. Alternatively, the first mask layer 120 may be formed of a silicon oxide layer and the second mask layer 130 may be formed or a silicon nitride layer. The second mask layer 130 may have an etch selectivity with respect to the first mask layer 120. In this respect, it should be noted that “having an etch selectivity” indicates that one layer may be etched while minimizing the etching of another layer. For example, the second mask layer 130 may be etched while minimizing the etching of the first mask layer 120 and vice versa. Next, a photoresist pattern 140 may be formed on the second mask layer 130.

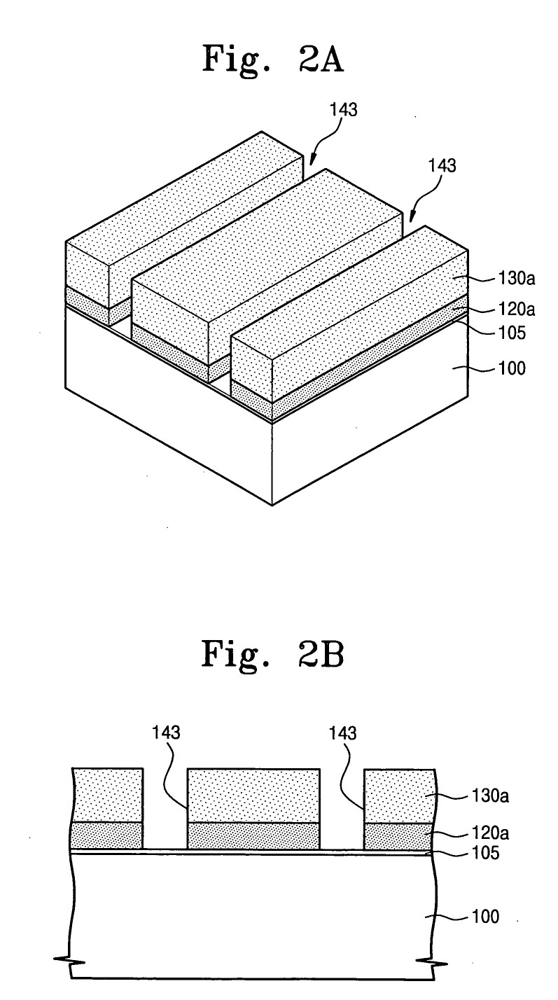

As illustrated in FIGS. 2A-2B, the photoresist pattern 140 may be used as an etch mask to etch the first and second mask layers 120 and 130 to form a first mask pattern 120a and a second mask pattern 130a, respectively. In particular, the first and second mask patterns 120a and 130a may be formed to include a plurality of first openings 143. The plurality of first openings 143 may have a predetermined depth, i.e., a vertical distance as measured from an upper surface of the pad oxide layer 105 to an upper surface of the second mask pattern 130a along a y-axis, and a linear shape, e.g., trenches arranged in parallel to one another along an x-axis.

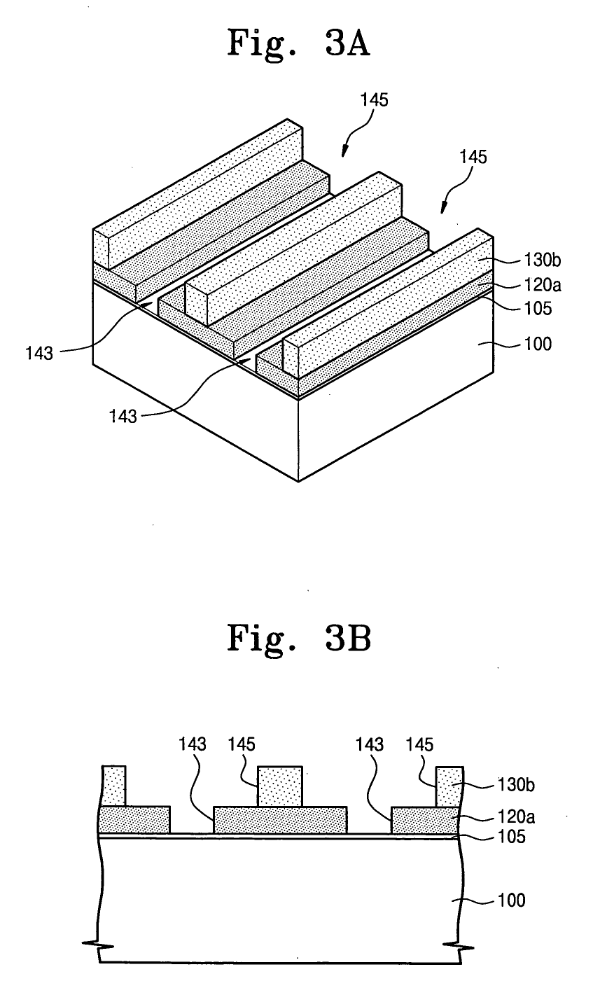

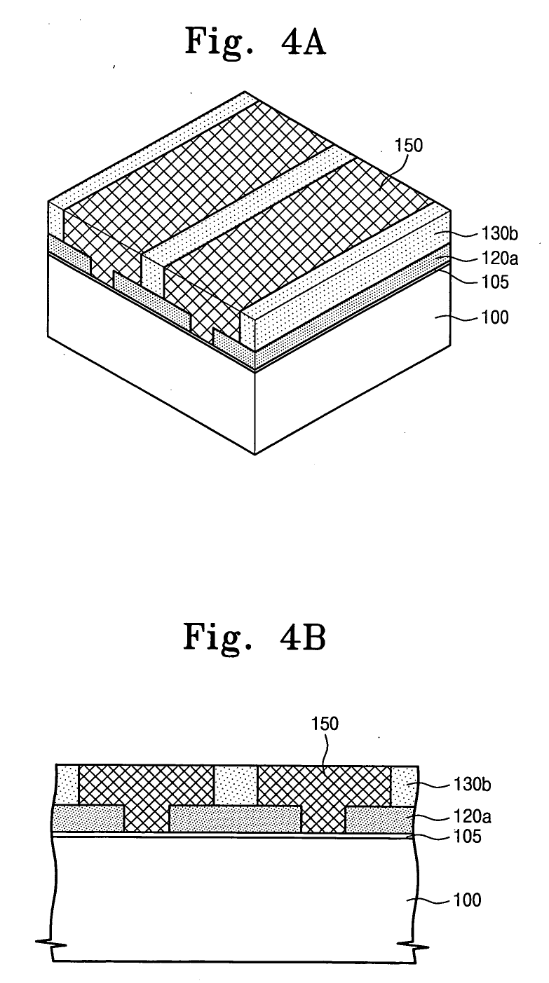

Next, referring to FIGS. 3A-3B, an upper portion of the plurality of first openings 143, i.e., a portion in communication with the second mask pattern 130a, may be widened, i.e., expanded along a z-axis, to form a second fine mask pattern 130b having a plurality of linear portions and openings therebetween. In particular, the second fine mask pattern 130b may include a plurality of linear portions extending along the x-axis in parallel to the plurality of the first openings 143. Each such linear portion of the second fine mask pattern 130b may have a width, i.e., a distance as measured along the z-axis, equal to a width of each of the first openings 143. Additionally, the second fine mask pattern 130b may have a plurality of second openings 145 that may be larger in width than the plurality of the first openings 143. A width of the first mask pattern 120a may remain substantially unchanged.

Formation of the second fine mask pattern 130b may include performing a pull-back process. The pull-back process may include immersing the semiconductor substrate 100 into an etching solution, such that sidewalls of the second mask pattern 130a may be etched to form the plurality of second openings 145. When the second mask pattern 130a includes a silicon nitride layer, the etching solution of the pull-back process may be a phosphoric acid (H₃PO₄)-containing solution. When the second mask pattern 130a includes a silicon oxide layer, the etching solution of the pull-back process may be a hydrofluoric acid (HF)-containing solution. The second mask pattern 130a may have an etch selectivity with respect to the first mask pattern 120a.

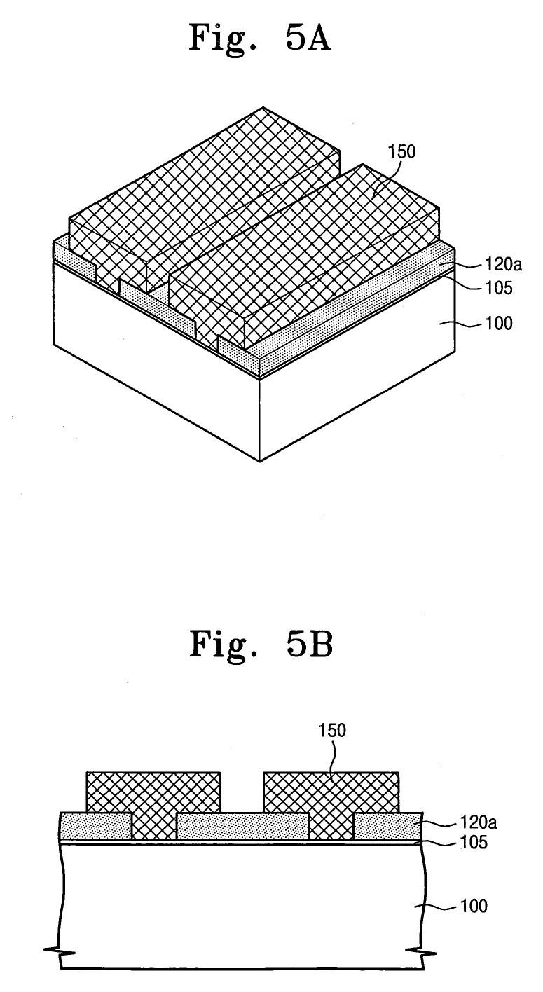

Referring to FIGS. 4A-4B, a third mask pattern 150 may be deposited in the plurality of first and second openings 143 and 145, such that inner sidewalls of the plurality of first and second openings 143 and 145 may be completely filled with the third mask pattern 150, and an upper surface of the second fine mask pattern 130b may be exposed to the exterior. In particular, formation of the third mask pattern 150 may include depositing a third mask layer (not shown), e.g., a polysilicon layer formed by low-pressure CVD (LPCVD), to cover the second fine mask pattern 130b, the first mask pattern 120a, and the pad oxide layer 105; and planarizing the third mask layer to expose the upper surface of the second fine mask pattern 130b. The third mask layer may have an etch selectivity with respect to the first mask layer 120 and the second mask layer 130.

Referring to FIGS. 5A-5B, an etching process may be performed to remove, the second line mask pattern 130b. Removal of the second fine mask pattern 130b may include performing a wet etching process. The wet etching process may have an etch selectivity with respect to the second fine mask pattern 130b rather than the third mask pattern 150. The third mask pattern 150 may be a polysilicon layer and the second fine mask pattern 130b may be a silicon oxide layer or a silicon nitride layer.

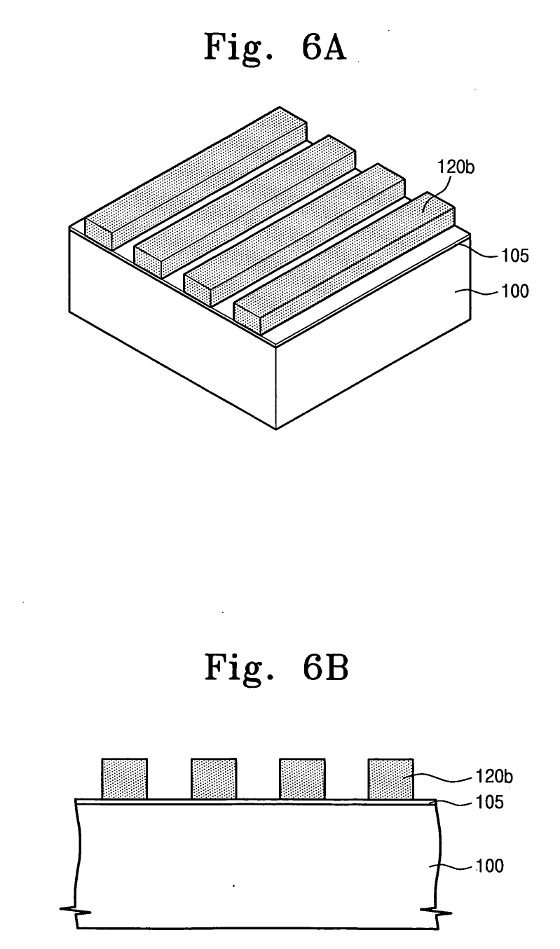

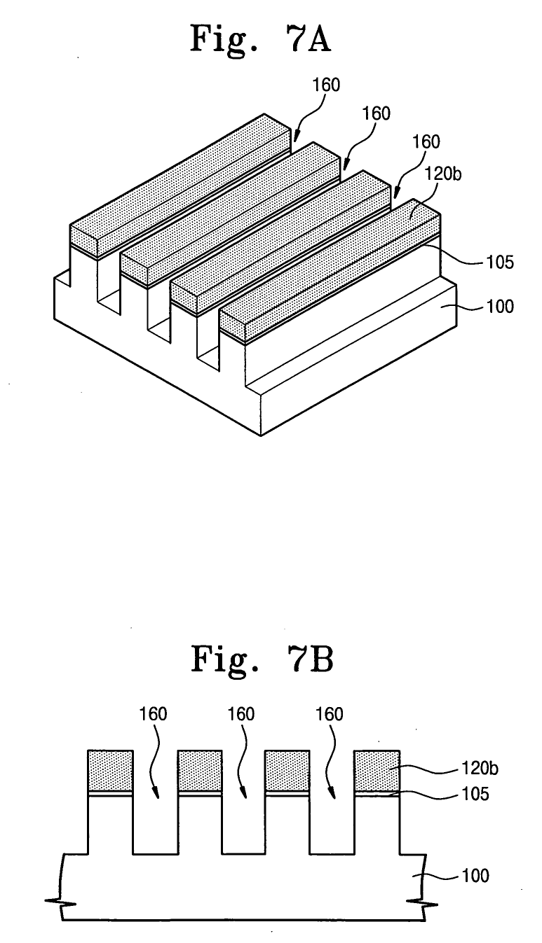

Referring to FIGS. 6A-6B, the third mask pattern 150 may be used as an etch mask to etch the first mask pattern 120a to form a first fine mask pattern 120b. The first fine mask pattern 120b may have the shape of lines that may be arranged in parallel in one direction. The third mask pattern 150 may be removed to expose the first fine mask pattern 120b. Removal of the third mask pattern 150 may include performing a wet etching process. The wet etching process may have an etch selectivity with respect to the third mask pattern 150 rather than the first fine mask pattern 120b. The lines of the first fine mask pattern 120b may be arranged at regular intervals.

Referring to FIGS. 7A-7B, the first fine mask pattern 120b may be used as an etch mask to etch the semiconductor 100 to form a plurality of trenches 160 therein. Formation of the plurality of trenches 160 may include performing a plasma dry etching process. Because the plurality of first openings 143 and the second fine mask pattern 130b may have an equal width, all the trenches 160 may have a uniform width.

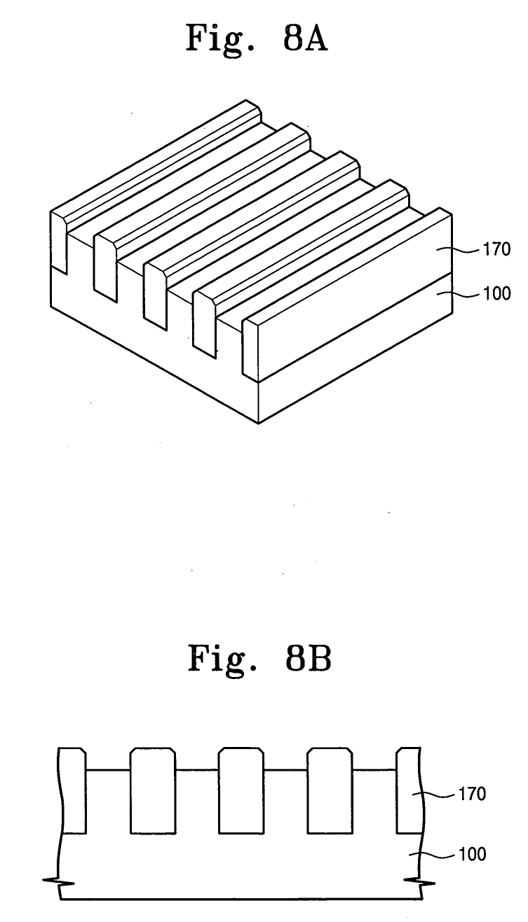

Referring to FIGS. 8A-8B, a device isolation layer 170 may be formed to fill the plurality of trenches 160. Formation of the device isolation layer 170 may include filling the plurality of trenches 160 with a silicon oxide layer by CVD and performing a planarization process to an upper surface of the first fine mask pattern 120b. Next, the first fine mask pattern 120b and the pad oxide layer 105 may be removed to define an active region by the device isolation layer 170. In other words, formation of a plurality of trenches 160 having a uniform width may facilitate formation therein of a device isolation layer 17u0 having a plurality of linear portions with uniform widths.

According to an exemplary embodiment of the present invention the second fine mask pattern 130b formed by the pull-back process may be advantageously used to form a device isolation layer 170 and active regions thereon with a reduced uniform linewidth. Accordingly, a gate line may be formed across the device isolation layer 170 and the active region. The gate line may include a tunnel insulating layer, a charge storage layer, a blocking insulating layer, and a control gate.

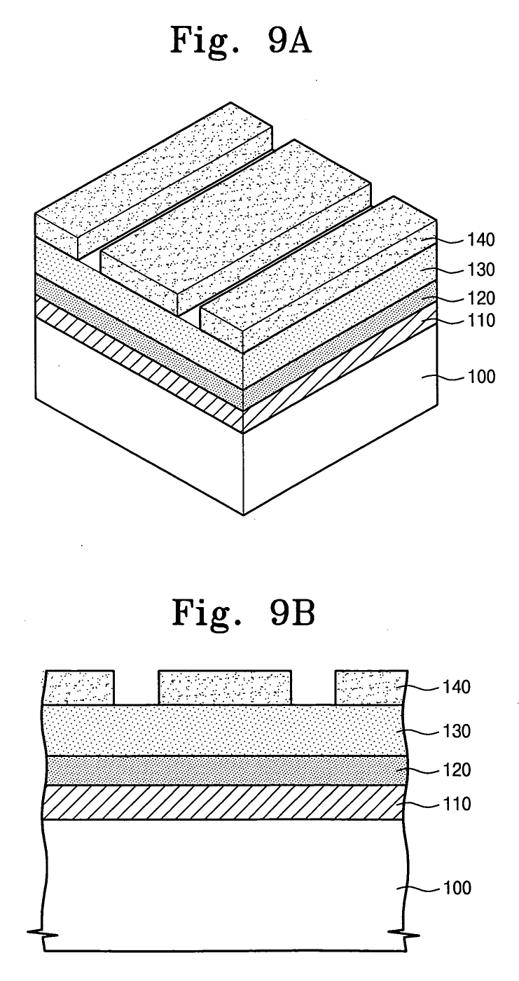

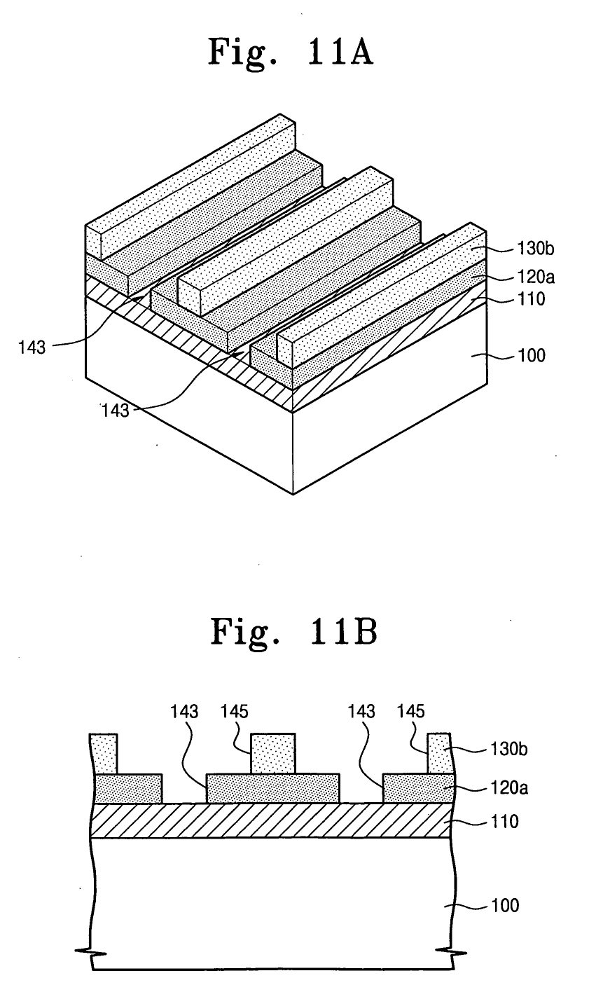

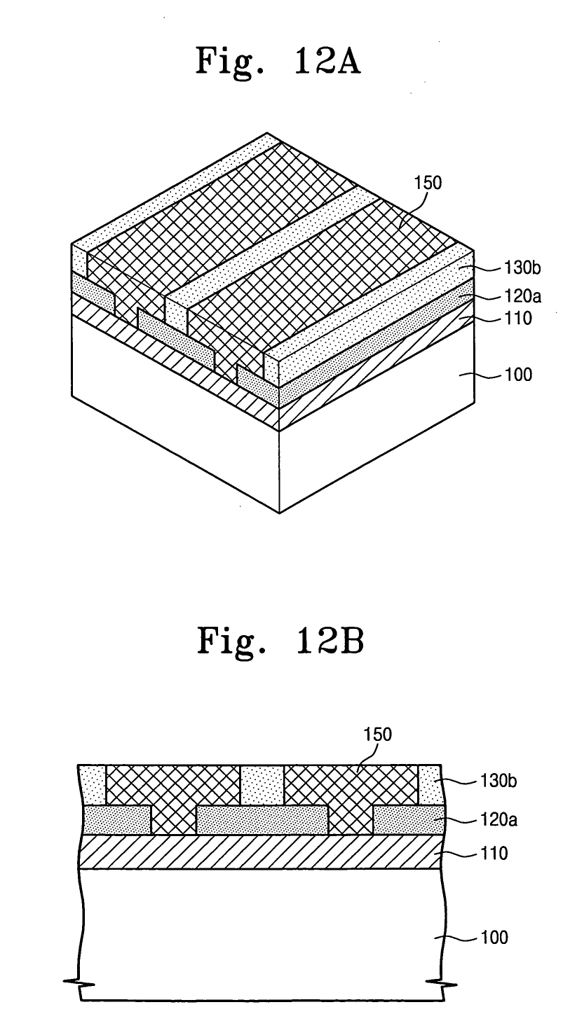

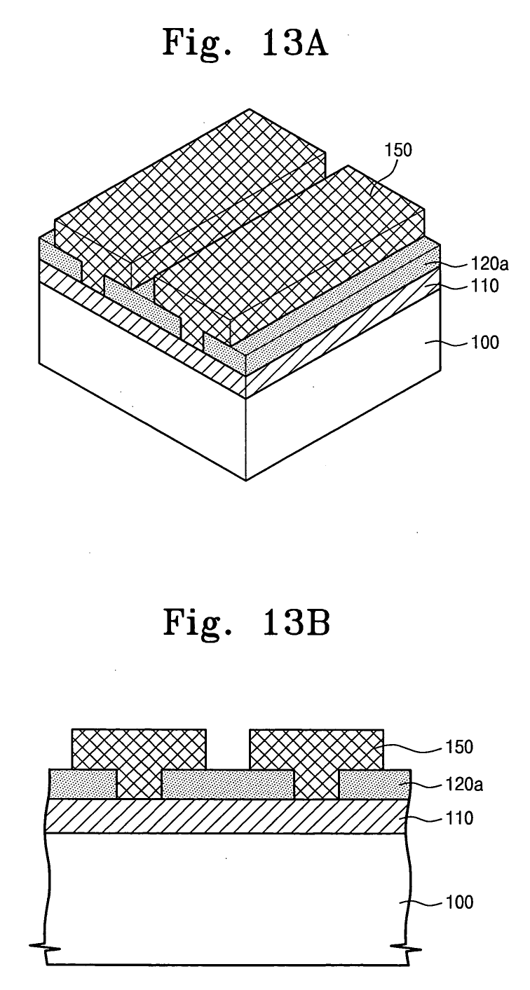

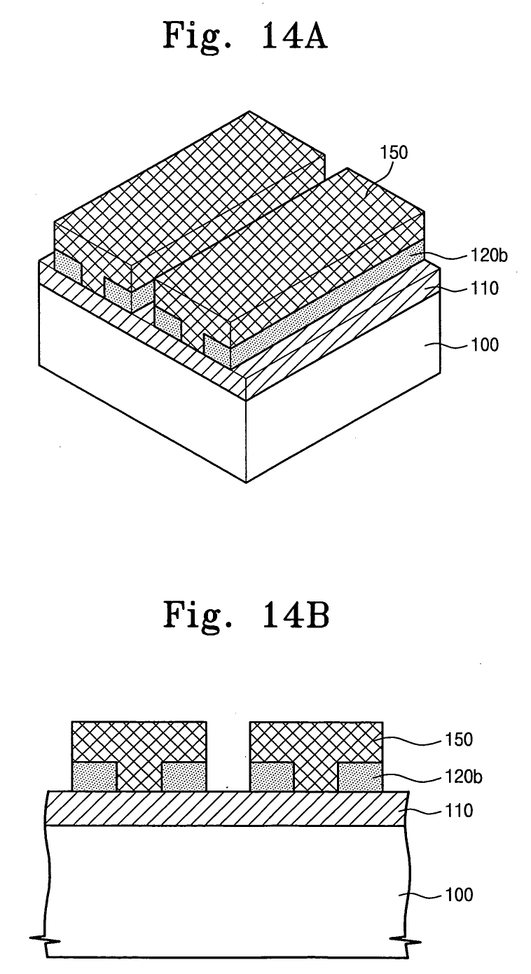

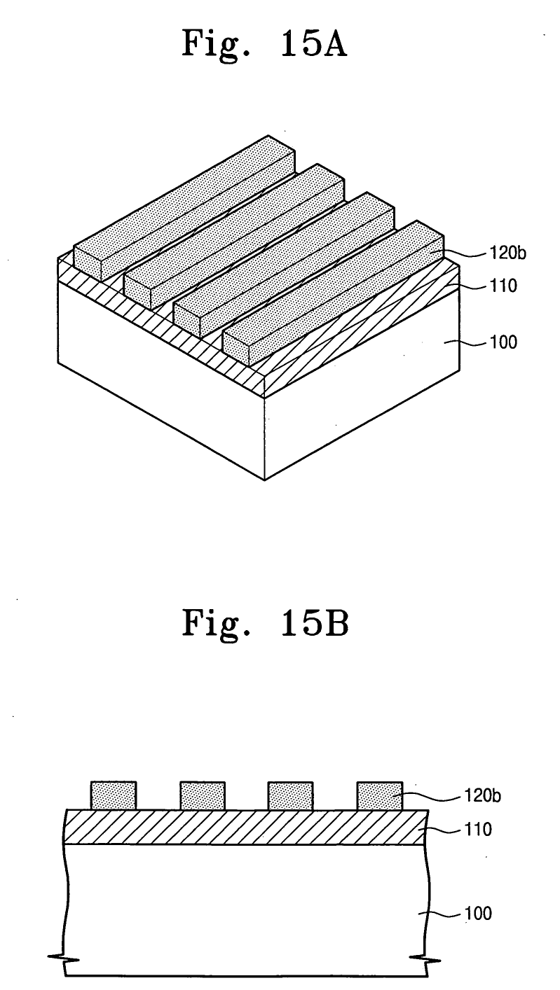

According to another exemplary embodiment of the present invention, another method of fabricating a semiconductor device will be illustrated with respect to FIGS. 9A-16B.

Referring to FIGS. 9A-9B, a line layer 110 may be formed on a semiconductor substrate 100. The line layer 110 may include a gate layer for a gate pattern or a metal layer for a bit line. A first mask layer 120, a second mask layer 130 and a photoresist pattern 140 may be sequentially formed on the line layer 110 as previously described with respect to FIGS. 1A-1B.

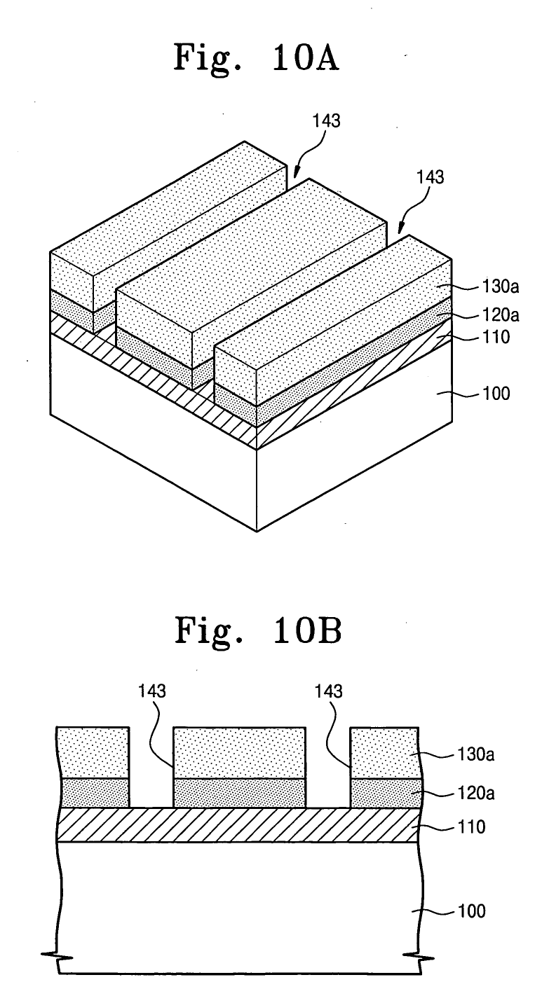

Referring to FIGS. 10A-15B, a first fine mask pattern 120b may be formed on the line layer 110 in the same manner as previously described with reference to FIGS. 2A-6B. The first fine mask pattern 120b may include a plurality of linear portions arranged in parallel in one direction.

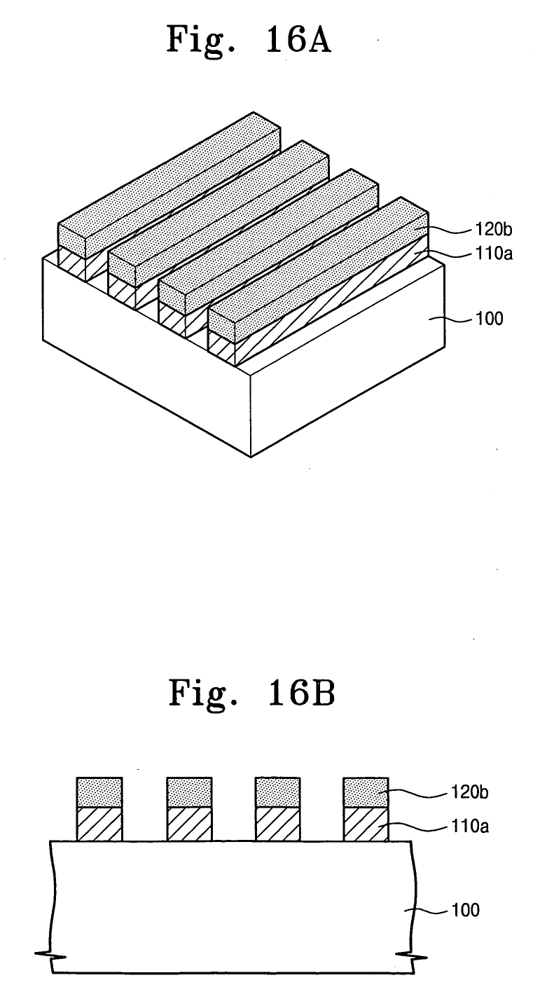

Referring to FIGS. 16A-16B, the first fine mask pattern 120b may be used as an etch mask to etch the line layer 110 to form line patterns 110a. The line patterns 110a may include gate patterns or bit lines. Alternatively, a pull-back process may be performed to form a second fine mask pattern 130b in order to facilitate formation of gate patterns or bit lines with reduced linewidth or intervals.

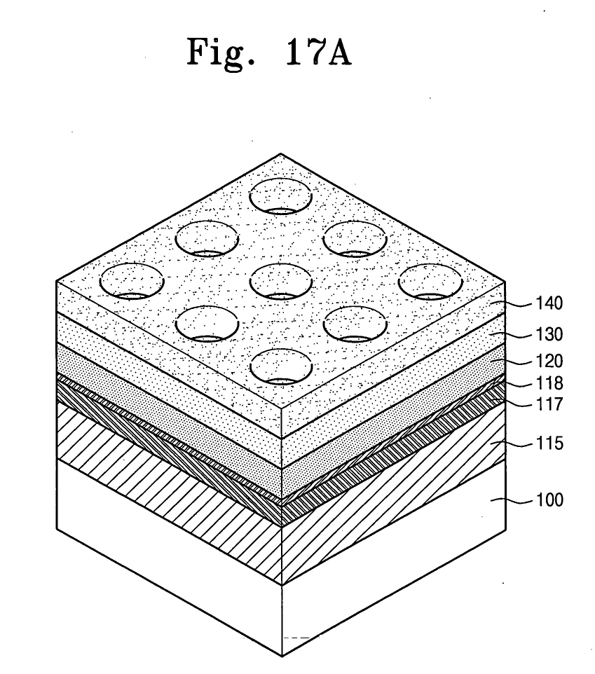

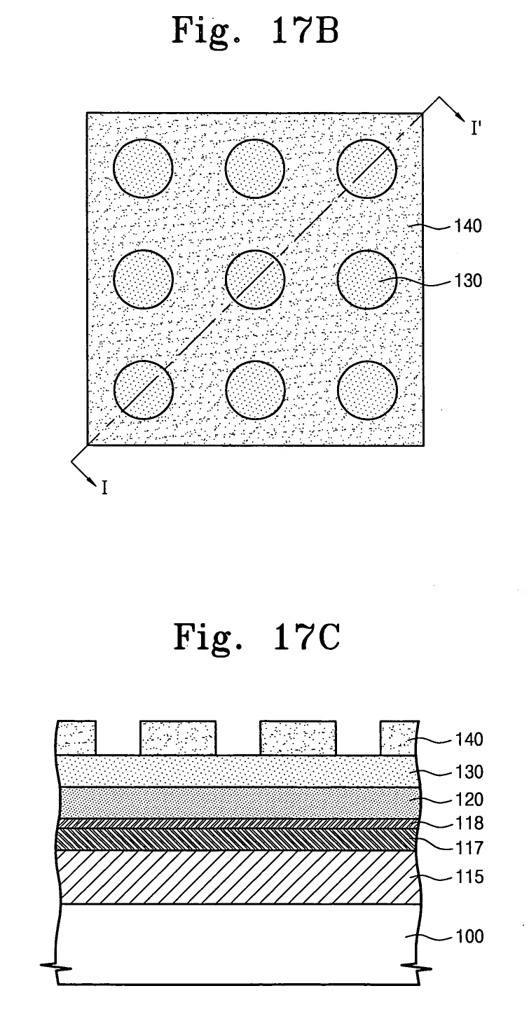

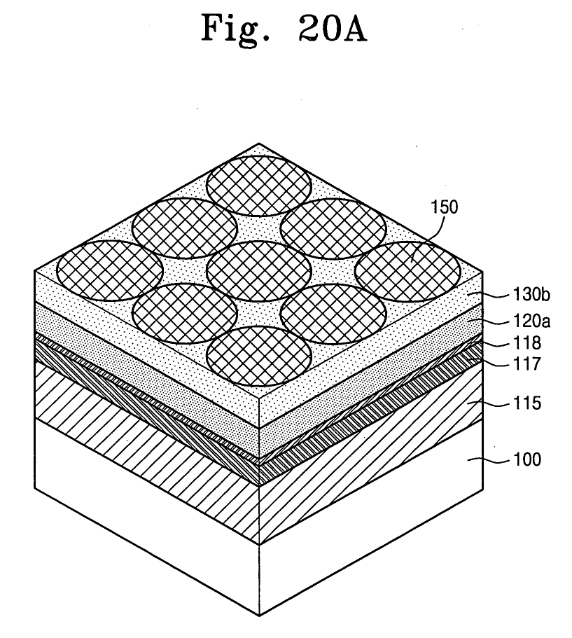

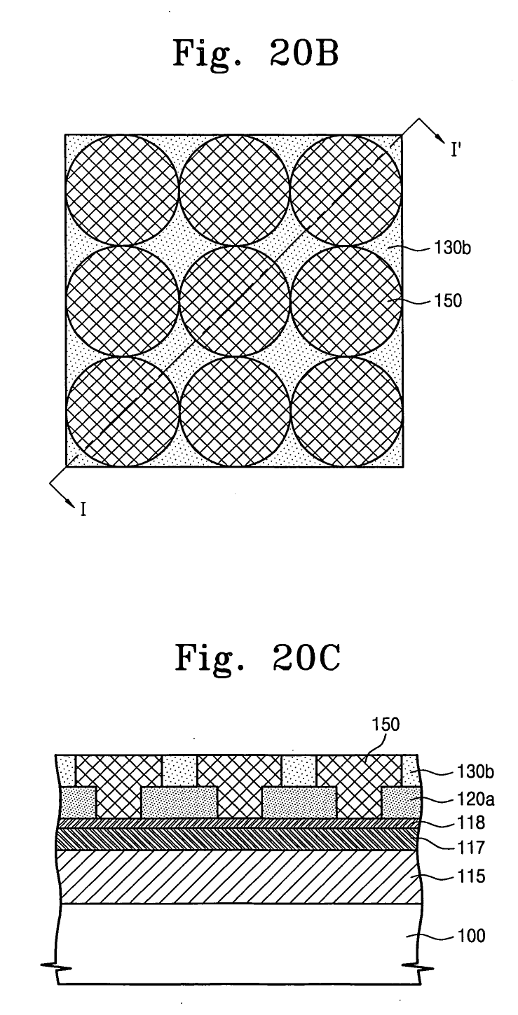

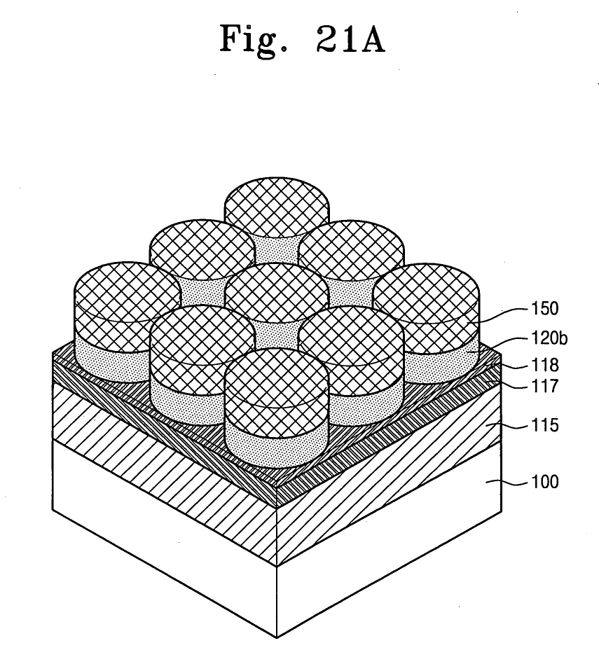

According to yet another exemplary embodiment of the present invention, another method of fabricating a semiconductor device will be illustrated with respect to FIGS. 17A-24C.

Referring to FIGS. 17A-17C, a mold oxide layer 115 may be formed on a semiconductor substrate 100. The semiconductor substrate 100 may include a transistor, a storage node contact, and a bit line. The mold oxide layer 115 may be formed of a silicon oxide layer by CVD. An amorphous carbon layer 117 may be formed on the mold oxide layer 115 by CVD. An anti-reflective layer 118 may be formed by depositing a silicon nitride oxide layer on the amorphous carbon layer 117 by CVD. A first mask layer 120, a second mask layer 130, and a photoresist pattern 140 may be formed sequentially on the anti-reflective layer 118 as previously described with respect to FIGS. 1A-1B.

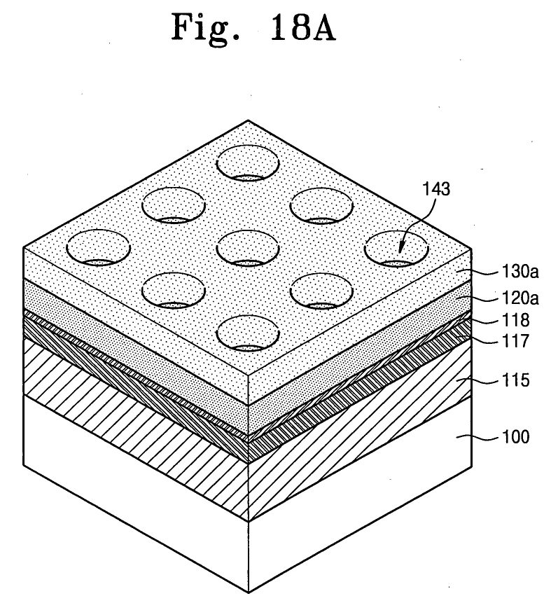

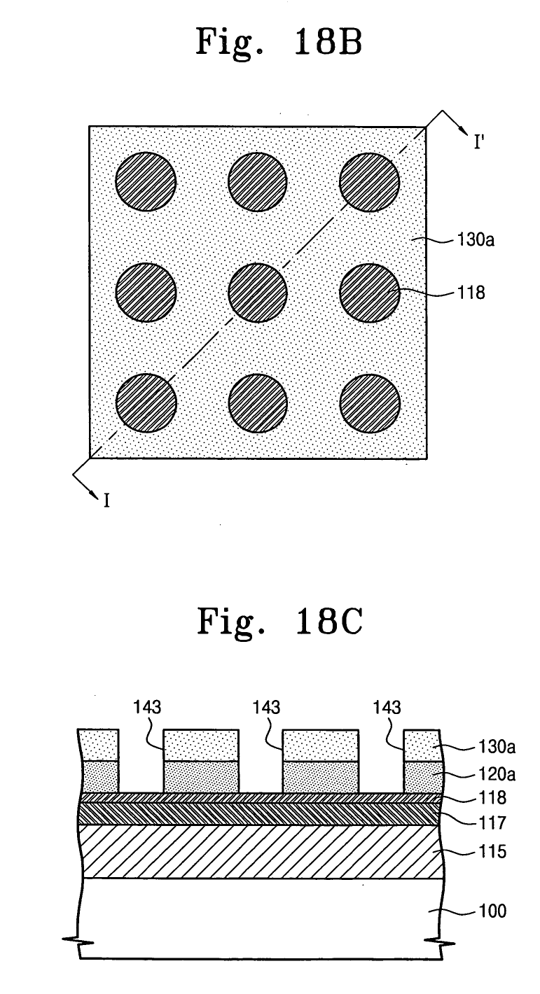

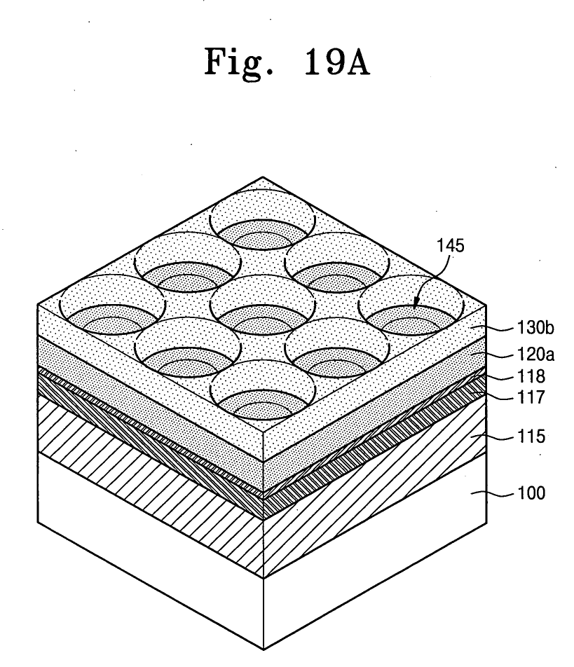

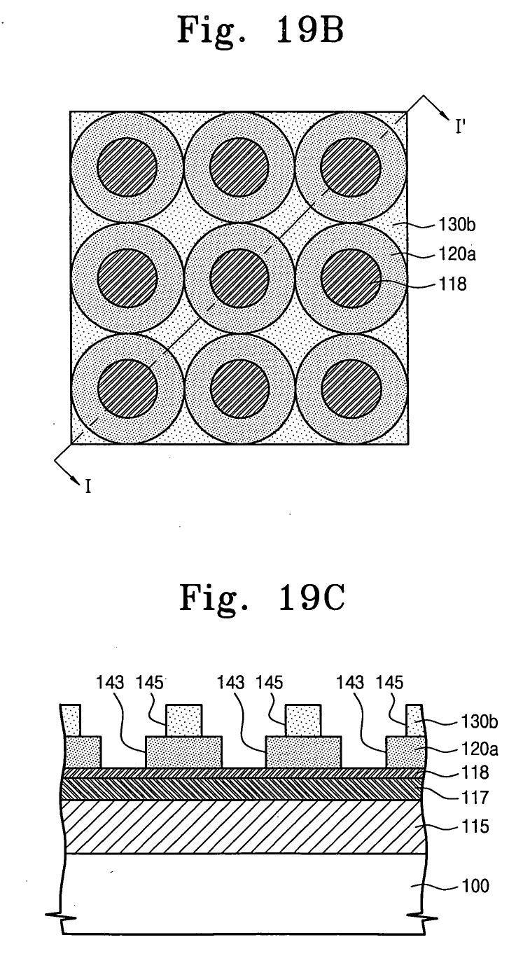

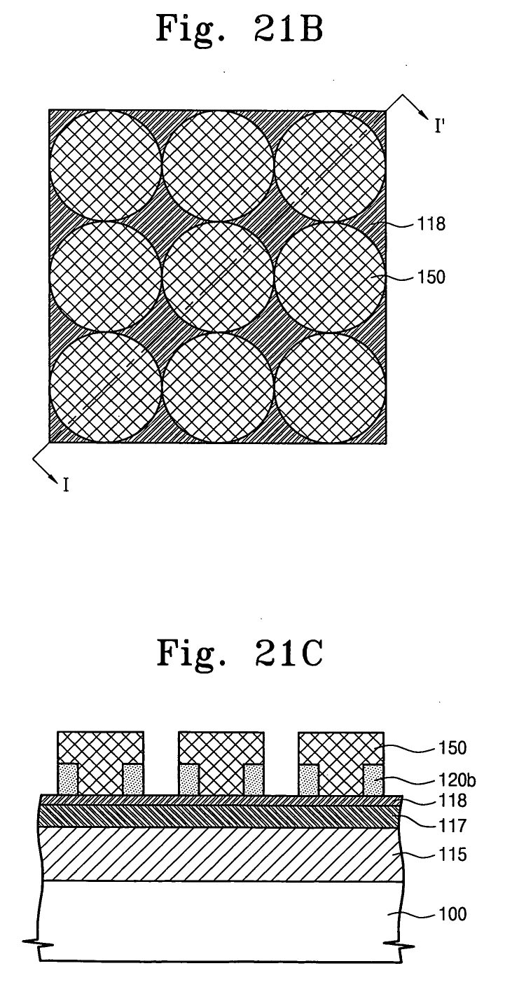

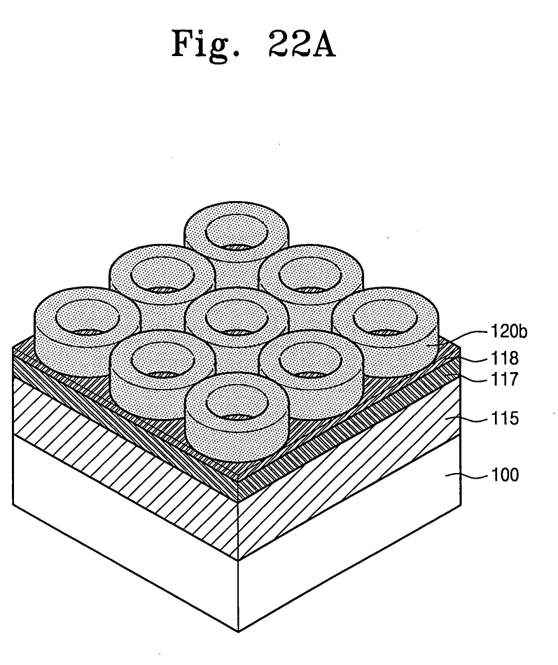

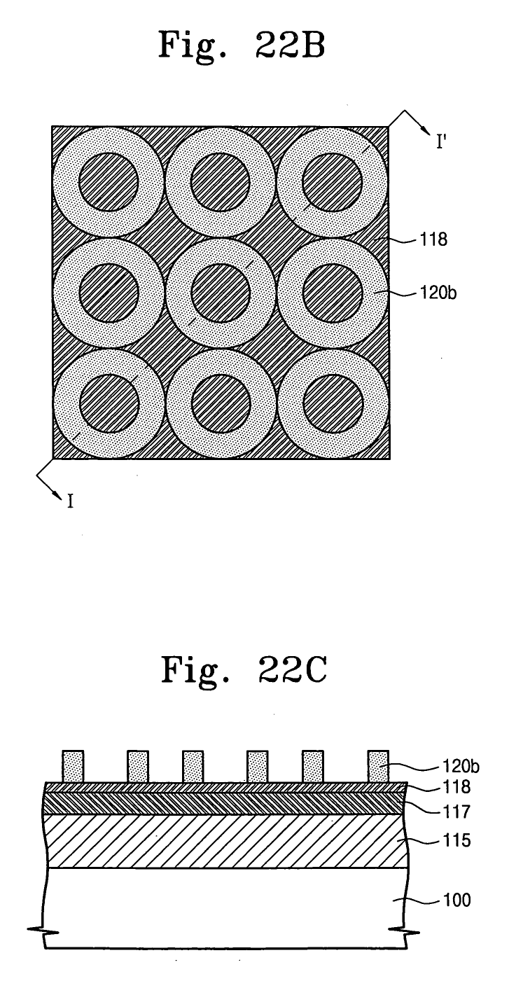

Referring to FIGS. 18A-22C, a first fine mask pattern 120b may be formed on the anti-reflective layer 118 as previously described with reference to FIGS. 2A-6B. However, the plurality of first openings 143 in communication with the first mask pattern 120a, i.e., a lower portion of the first openings 143, and the plurality of second openings 145 may have a circular shape as opposed to a linear shape, as illustrated in FIGS. 19A-19C. In particular, the plurality of second openings 145 may have a larger size, i.e., larger radius, as compared to a size of the plurality of first openings 143. Accordingly, the first fine mask pattern 120b may have a cylindrical shape with a circular or elliptical planar cross-section, as illustrated in FIGS. 21A-22B.

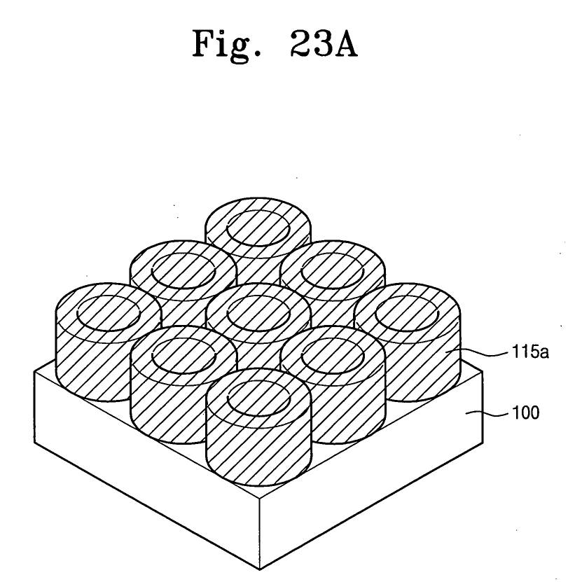

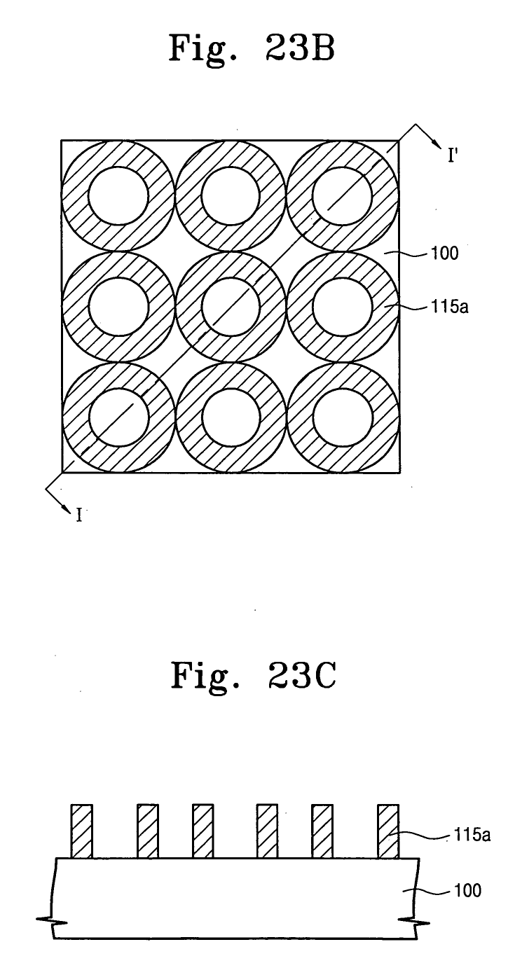

Referring to FIGS. 23A-23C, the cylindrical first fine mask pattern 120b may be used as an etch mask to etch the anti-reflective layer 118, the amorphous carbon layer 117, and the mold oxide layer 115 to form a mold oxide layer pattern 115a. The amorphous carbon layer 117 and the anti-reflective layer 118 may function as a hard mask layer during the formation of the mold oxide layer pattern 115a and be removed thereafter.

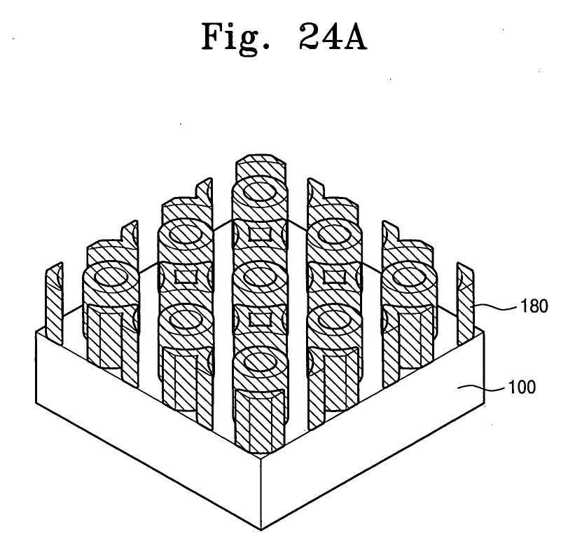

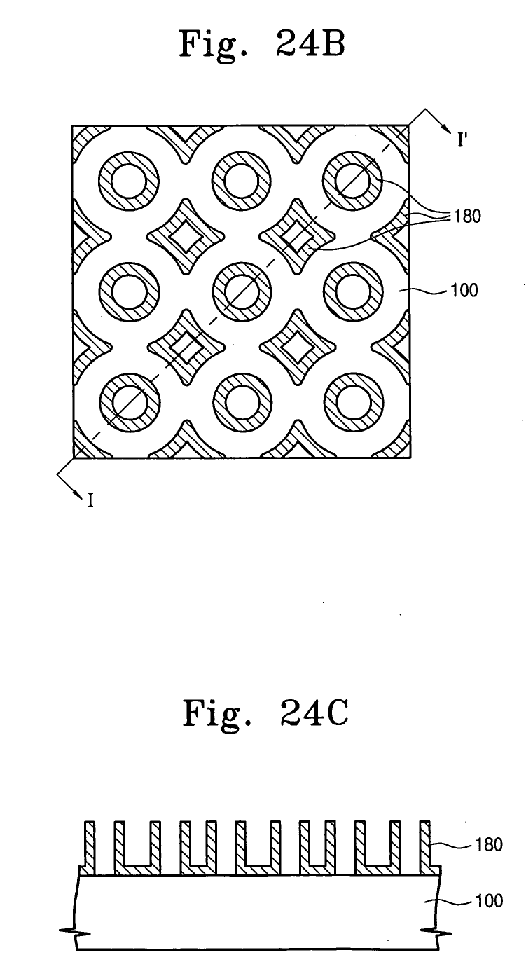

Referring to FIGS. 24A-24C, a lower electrode or a storage node 180 may be formed on a side of the mold oxide layer pattern 115a. The lower electrode 180 may be connected to a storage node contact (not shown) of the semiconductor substrate 100. Formation of the storage node 180 may include forming a metal layer to conformally cover the mold oxide layer pattern 115a, forming a sacrificial oxide layer to fill an opening of the metal layer, planarizing the sacrificial oxide layer to expose the mold oxide layer pattern 115a, and removing the sacrificial oxide layer and the mold oxide layer pattern 115a. Alternatively, a second fine mask pattern may be formed using a pull-back process. The mold oxide layer pattern 115a, which may be small in linewidth and can be used in DRAMs, can be formed using the second fine mask pattern.

According to the exemplary embodiments of the present invention, the second fine mask pattern with a reduced linewidth may be formed using a pull-back process. Accordingly, patterns of a highly-integrated semiconductor device can be formed without making an additional investment for the exposure equipment.

In addition, because the trenches, the gate patterns, the bit lines, and the lower electrodes may be formed after the pull-back process, the respective patterns can have a constant profile. Accordingly, it may be possible to fabricate a semiconductor device having patterns with a reduced linewidth.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, comprising:
forming a first mask layer on a semiconductor substrate;
forming a second mask layer on the first mask layer;
patterning the first mask layer and the second mask layer to form a first mask pattern and a second mask pattern, respectively, the first and second mask layers having a plurality of first openings;
widening an upper portion of the plurality of first openings to form a second fine mask pattern with a plurality of second openings having a larger width as compared to a width of the plurality of the first openings;
forming a third mask pattern in the plurality of first and second openings;
removing the second fine mask pattern; and
etching the first mask pattern to form a first fine mask pattern.

2. The method as claimed in claim 1, wherein the second fine mask pattern is formed to have a width equal to a width of each of the plurality of the first openings.

3. The method as claimed in claim 1, wherein etching the first mask pattern to form the first fine mask pattern includes removing the third mask pattern to expose the first fine mask pattern.

4. The method as claimed in claim 3, wherein the first fine mask pattern is formed to have parallel lines in one direction.

5. The method as claimed in claim 3, further comprising:
forming a plurality of trenches in the semiconductor substrate via the first fine mask pattern; and
forming a device isolation layer in the trenches.

6. The method as claimed in claim 3, further comprising:
forming a line layer on the semiconductor substrate before forming of the first mask layer; and
etching the line layer using the first fine mask pattern as an etch mask to form a line pattern.

7. The method as claimed in claim 1, wherein widening the upper portion of the plurality of first openings to form the second fine mask pattern includes performing a pull-back process.

8. The method as claimed in claim 1, wherein forming the third mask pattern includes:
forming a third mask layer on the second fine mask pattern and the first mask pattern; and
planarizing the third mask layer to expose an upper surface of the second fine mask pattern.

9. The method as claimed in claim 1, wherein the second mask layer is formed to have an etch selectivity with respect to the first mask layer.

10. The method as claimed in claim 9, wherein the second mask layer is formed of a silicon oxide layer and the first mask layer is formed of a silicon nitride layer.

11. The method as claimed in claim 9, wherein the second mask layer is formed of a silicon nitride layer and the first mask layer is formed of a silicon oxide layer.

12. The method as claimed in claim 1, wherein the second fine mask pattern is formed to have an etch selectivity with respect to the third mask pattern.

13. The method as claimed in claim 12, wherein the third mask pattern is formed of a polysilicon layer and the second fine mask pattern is formed of a silicon oxide layer or a silicon nitride layer.

14. The method as claimed in claim 1, further comprising forming a mold oxide layer on the semiconductor substrate.

15. The method as claimed in claim 14, wherein the plurality of first openings have circular shapes.

16. The method as claimed in claim 15, wherein the first fine mask pattern is formed as a plurality of cylinders.

17. The method as claimed in claim 16, further comprising etching the mold oxide layer via the fine mask pattern to form a cylindrical mold oxide layer pattern.

18. The method as claimed in claim 14, further comprising:
forming an amorphous carbon layer on the mold oxide layer; and
forming an anti-reflective layer on the amorphous carbon layer.

19. The method as claimed in claim 18, further comprising etching the amorphous carbon layer, the anti-reflective layer and the mold oxide layer via the fine mask pattern to form a cylindrical mold oxide layer pattern.

20. The method as claimed in claim 17, further comprising:
forming a metal layer with an opening on the cylindrical mold oxide layer pattern;
forming a sacrificial oxide layer to fill the opening of the metal layer;
planarizing the sacrificial oxide layer to expose the cylindrical mold oxide layer pattern; and
removing the sacrificial oxide layer and the cylindrical mold oxide layer pattern to form an electrode.
